(19) United States
(12) Patent Application Publication
(10) Pub. No.: US 2020/0033721 A1
(43) Pub. Date: Jan. 30, 2020

(54) NANO-IMPRINT TEMPLATE AND MANUFACTURING METHOD THEREOF

(71) Applicant: BOE Technology Group Co., Ltd., Beijing (CN)

(72) Inventors: Kang GUO, Beijing (CN); Xin GU, Beijing (CN)

(73) Assignee: BOE Technology Group Co., Ltd.

(21) Appl. No.: 16/419,514

(22) Filed: May 22, 2019

(30) Foreign Application Priority Data
Jul. 26, 2018 (CN) 201810833834.9

(51) Int. Cl. G03F 7/00; H01L 21/67

(52) U.S. Cl. CPC G03F 7/0002; B82Y 40/00; H01L 21/67092

(57) ABSTRACT

A nano-imprint template and a manufacturing method thereof are provided. The manufacturing method includes: forming a soft template on a side of at least one master provided with a preset pattern, wherein the soft template is provided with a groove corresponding to the preset pattern; forming a protective layer on a side of the soft template provided with the groove; moving at least one soft template formed with the protective layer into a stitching area of a base substrate; fixing at least one soft template on the base substrate, wherein the side of the soft template away from the protective layer contacts with the base substrate; and removing the protective layer.

### CROSS-REFERENCES TO RELATED APPLICATIONS

This application claims priority to Chinese patent application No. 201810833834.9 filed on Jul. 26, 2018, which is incorporated herein by reference in its entirety.

### TECHNICAL FIELD

The present disclosure relates to the technical field of semiconductors, and particularly to a nano-imprint template and a manufacturing method thereof.

### BACKGROUND

As a method of directly utilizing mechanical contact extrusion to redistribute an imprinted material between a template and a substrate, nano-imprint lithography (NIL) has the advantages of high resolution (<10 nm), simple process, low cost, high yield, mass production, etc., has become the most promising next-generation optical technology, and has a wide range of applications in display, semiconductor and other fields.

### SUMMARY

In one aspect, an embodiment of the present disclosure provides a manufacturing method of a nano-imprint template. The method includes: forming a soft template on a side of at least one master provided with a preset pattern, wherein the soft template is provided with a groove corresponding to the preset pattern; forming a protective layer on a side of the soft template provided with the groove; moving at least one soft template formed with the protective layer into a stitching area of a base substrate; fixing the at least one soft template on the base substrate, wherein a side of the soft template away from the protective layer contacts with the base substrate; and removing the protective layer.

In some embodiments, forming the soft template on the side of the at least one master provided with the preset pattern includes: coating a silica gel material or a resin material on the side of the at least one master provided with the preset pattern; and curing the silica gel material or the resin material to form the soft template.

In some embodiments, forming the protective layer on the side of the soft template provided with the groove includes: coating a soluble resin material on the side of the soft template provided with the groove.

In some embodiments, removing the protective layer includes: dissolving the soluble resin material.

In some embodiments, the soluble resin material is Polyvinyl Alcohol.

In some embodiments, moving at least one soft template formed with the protective layer into the stitching area of a base substrate includes: bonding the protective layer and a transfer head by a heat release tape to fix the soft template formed with the protective layer to the transfer head; moving the transfer head into the stitching area of the base substrate; and heating the heat release tape until the soft template is detached from the transfer head.

In some embodiments, fixing the at least one soft template on the base substrate includes heating the base substrate until the soft template is fixed on the base substrate.

In another aspect, the embodiment of the present disclosure further provides a nano-imprint template manufactured by using the manufacturing method according to any one of the above technical solutions. The nano-imprint template includes: a base substrate; and a plurality of soft templates fixed on the base substrate, wherein a side of at least one of the soft templates away from the base substrate is provided with a groove.

In some embodiments, the soft templates are prepared by using a silica gel material or a resin material.

In some embodiments, a height difference of any two adjacent ones of the soft templates is about 0.

### BRIEF DESCRIPTION OF THE DRAWINGS

FIG. 1 is a schematic flow chart of manufacturing of a nano-imprint template according to an embodiment of the present disclosure;

FIG. 2 is a schematic structural diagram of a nano-imprint template according to an embodiment of the present disclosure;

FIG. 3 is a schematic flow chart of preparing of a soft template according to an embodiment of the present disclosure;

FIG. 4 is a schematic flow chart of preparing of a soft template with a protective layer according to an embodiment of the present disclosure;

FIG. 5 is a section view of a nano-imprint template according to an embodiment of the present disclosure; and

FIG. 6 is a schematic flow chart of fixing of a plurality of soft templates on a base substrate according to an embodiment of the present disclosure.

### DETAILED DESCRIPTION

In order to make the objects, technical solutions and advantages of the embodiments of the present disclosure clearer, the technical solutions of the embodiments of the present disclosure will be clearly and completely described below in conjunction with the drawings of the embodiments of the present disclosure. It is apparent that the described embodiments are part of the embodiments of the present disclosure, but not all of the embodiments. All other embodiments obtained by those ordinary skilled in the art based on the described embodiments of the present disclosure without departing from the scope of the disclosure are within the scope of the present disclosure.

Technical terms or scientific terms used in the present disclosure, unless otherwise defined, are intended to be in the ordinary meaning as understood by those ordinary skilled in the art. The words “first”, “second” and similar terms used in the present disclosure do not denote any order, quantity, or importance, but are used to distinguish different components. The words “comprising” or “including” and the like mean that the element or the object preceding the word contains the elements or objects listed after the word and its equivalent, without excluding other elements or objects. The words “connecting” or “linking” and the like are not limited to physical or mechanical connections, but may include electrical connections, whether direct or indirect. “Upper”, “lower”, “left”, “right”, etc. are only used to indicate the relative positional relationship, and when the absolute position of the object to be described is changed, the relative positional relationship may also change accordingly.

In order to keep the following description of the embodiments of the present disclosure clear and concise, the present disclosure omits detailed descriptions of known functions and known parts.

In the related art, since the display substrate is gradually developed from a small size to a large size, a large-sized nano-imprint template is required corresponding thereto. The nano-imprint template is manufactured by electron beam direct writing technology through nano-imprinting equipment, which takes a long time. Generally the nano-imprint template is made under 6 inches, and it is difficult to make a large-sized nano-imprint template. For the large-sized nano-imprint template, it is usually completed by stitching multiple nano-imprint templates, the template stitching is completed by sequentially performing the process of dispensing imprinting glue-imprinting-UV curing in the area, corresponding to the small-sized nano-imprint template, on the substrate. Since the method of stepwise dispensing is used, the imprinting glue that exceeds the imprinted area may flow into the remaining area due to the overflow at the boundary during imprinting, so that the imprinting glue in the remaining area is more, resulting in a greater thickness after imprinting, the height of adjacent areas is different, the edge position of each area is difficult to be flat, there are some problems such as larger stitching seam and imprinting loss caused by the height difference at the stitching seam, and the poor quality of imprinting at the stitching seam also affects the yield of large-sized nano-imprint templates.

The present disclosure provides a nano-imprint template and a manufacturing method thereof, which can improve the problem of the imprinting loss caused by the lager stitching seam and the problem of the height difference at the stitching seam of the nano-imprint templates in the related art.

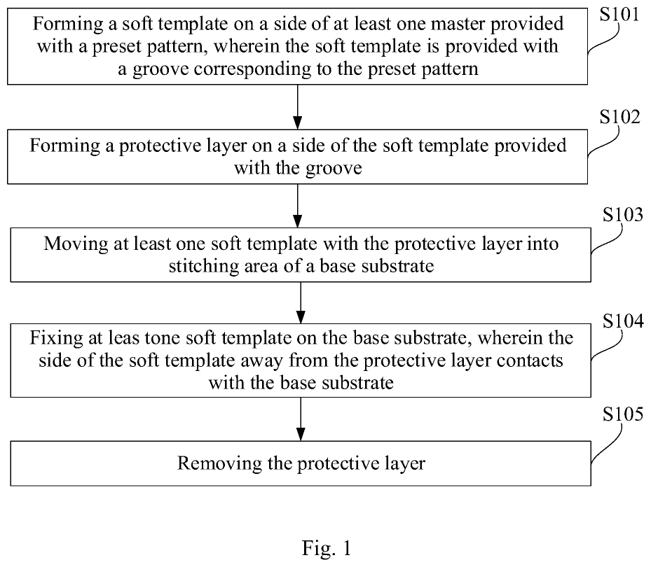

Referring to FIG. 1, an embodiment of the present disclosure provides a manufacturing method of a nano-imprint template, which includes the following steps.

Step S101 is to form a soft template 2 on a side of each master 4 provided with a preset pattern 41, wherein the soft template 2 is provided with a groove 21 corresponding to the preset pattern 41.

Step S102 is to form a protective layer 3 on a side of the soft template 2 provided with the groove 21.

Step S103 is to move at least one soft template 2 formed with the protective layer 3 into a stitching area of a base substrate 1.

Step S104 is to fix at least one soft template 2 on the base substrate 1, wherein a side of the soft template 2 away from the protective layer 3 contacts with the base substrate 1.

Step S105 is to remove the protective layer 3.

In the manufacturing method of the nano-imprint template, as shown in FIG. 3, the soft template 2 is first formed in the step S101, and the groove 21 on the soft template 2 corresponds to the preset pattern 41 on the master 4, that is, each soft template 2 has partial graphic information of the nano-imprint template. As shown in FIG. 4, the protective layer 3 is then formed in the step S102, since the soft templates 2 need to be transferred and fixed before the final formation of the nano-imprint template, moreover, the grooves 21 may be damaged during the transfer and fixing process of the plurality of soft templates 2, so that the grooves 21 of the soft templates 2 can be protected from damage by arranging the protective layers 3 on the grooves 21. As shown in FIG. 6, then the soft templates 2 are moved one by one into the stitching area of the base substrate 1 in S103 and each of the soft templates 2 is fixed on the base substrate 1. As shown in FIG. 6, then in step S104, the process of fixing the soft templates 2 on the base substrate 1 is to move all soft templates 2 according to the direction A into the stitching area and then together fix the soft templates 2 on the base substrate 1, which is simple and convenient to implement; or the process can also be to move one soft template 2 into the stitching area and then fix the soft template 2 on the base substrate 1, then move next soft template 2 into the stitching area and fix, until all soft templates 2 are moved and fixed on the base substrate 1, which can ensure accurate positioning of the soft template 2 in the stitching area. As shown in FIG. 6, finally the protective layers 3 on the soft templates 2 are removed in step S105, and the stitching of the entire nano-imprint template is completed; a plurality of soft templates 2 are fixed on the base substrate 1, and the grooves 21 of the plurality of soft templates 2 correspond to the graphic information of the nano-imprint template, thereby the stitching process of the nano-imprint template is completed.

Compared with the stitching process in the related art, since the stepwise dispensing of the glue is not involved in the stitching process of the present disclosure, the thickness of the plurality of soft templates 2 prepared by the same method is uniform, and the formation and removal of the protective layers 3 do not cause a difference in thickness of the plurality of soft templates 2, and similarly the movement and fixation of the soft templates 2 do not cause a difference in thickness of the plurality of soft templates 2, so when the soft templates 2 are fixed on the base substrate 1, the overall thickness of the nano-imprint template is uniform, and there is no height difference at the stitching seam, which solves the problem of the imprinting loss caused by the height difference of the nano-imprint template at the stitching seam and the problem of the larger stitching seam, so that the imprinting quality at the stitching seam is good, and the product yield of the large-sized nano-imprint templates is improved.

In some embodiments, the step S101 of forming a soft template 2 on the side of each of the masters 4 provided with a preset pattern 41, as shown in FIG. 3, specifically includes: coating a silica gel material or a resin material on the side of each master 4 provided with the preset pattern 41; and curing the silica gel material or the resin material to form the soft template 2.

In the manufacturing method of the nano-imprint template, the material of the masters 4 may be a hard material such as silicon or quartz, and each master 4 is provided with a preset pattern 41, and the preset patterns 41 carry the partial graphic information of the nano-imprint template. In the implementation, each soft template 2 can use a flexible substrate, the preset pattern 41 on each master 4 is imprinted onto the flexible substrate by using a nano-imprint method, so that a groove 21 corresponding to each pattern 41 is formed on the flexible substrate, wherein the flexible substrate is made of a soft material, such as silica gel or resin material, and since the soft templates 2 prepared by imprinting of a flexible substrate with a fixed thickness, thus the thickness of the soft templates 2 and the depth of the grooves 21 can be accurately controlled. Or the soft template 2 can also be formed by coating a silica gel material or a resin material on the side of each master 4 provided with the preset pattern 41, and then curing the silica gel material or the resin material, in this way, the material of the soft templates can be a polymer easy to demold and low in viscosity, such as silica gel or resin material, this method for preparing the soft templates 2 is simple in process and easy to implement. The soft templates 2 can be prepared by the above two methods, and other preparation methods capable of meeting the requirements can also be used.

In some embodiments, the step S102 of forming a protective layer 3 on the side of the soft template 2 provided with the groove 21, as shown in FIG. 4, includes: coating a soluble resin material on the side of the soft template 2 provided with the groove 21. Specifically, the soluble resin material may be PVA (polyvinyl alcohol).

In the above manufacturing method of nano-imprint template, since the protective layers 3 will be finally removed from the soft templates 2, in order to avoid damage to the soft templates 2 when the protective layers 3 are removed from the soft templates 2, in the specific implementation, the protective layers 3 are prepared by a soluble resin material, it is only necessary to dissolve the protective layers 3 when the protective layers 3 are removed, and no other mechanical operation is required to avoid damage to the grooves 21 of the soft templates 2, not only the product yield can be improved and the operation is easy to implement. The soluble resin material may be a water-soluble resin material such as PVA (polyvinyl alcohol), or a resin material which is usually soluble in an organic solvent. In order to facilitate the removal of the protective layers 3, it is not limited to the above dissolution method, and may be other materials or structural forms that are easy to remove.

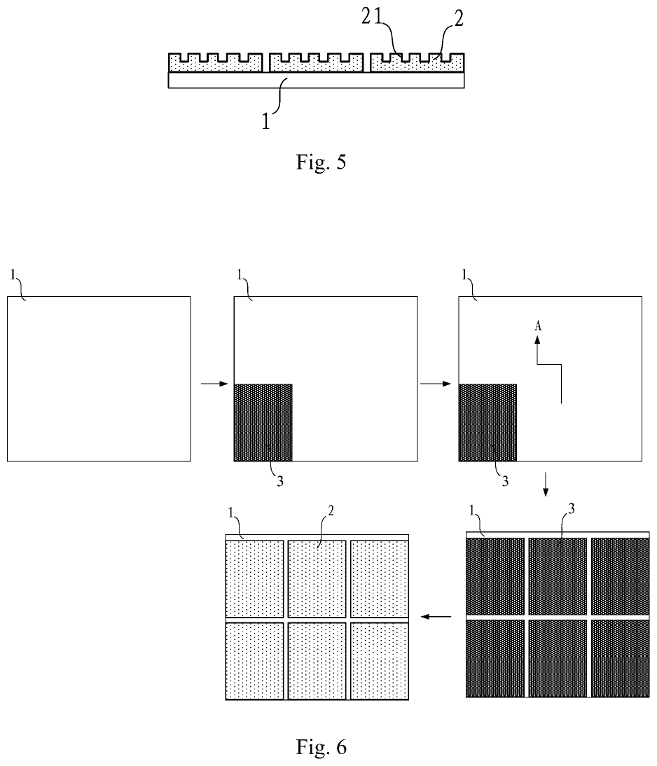

Correspondingly, the step S105 of removing the protective layers 3, as shown in FIG. 5, includes dissolving the soluble resin material.

In the above manufacturing method of the nano-imprint template, when the protective layers 3 are prepared by the soluble resin material, the protective layers 3 can be removed by the solvent corresponding to the soluble resin material, the above removal process is relatively simple in operation, easy to implement, and does not cause damage to the soft templates 2, thereby the product yield is improved.

In some embodiments, the step S103 of moving at least one soft template 2 formed with the protective layer 3 into a stitching area of a base substrate 1 specifically includes: bonding the protective layer 3 and a transfer head by a heat release tape to fix the soft template 2 formed with the protective layer 3 on the transfer head; moving the transfer head into the stitching area of the base substrate 1; and heating the heat release tape until the soft template 2 is detached from the transfer head.

In the above manufacturing method of the nano-imprint template, when a soft template 2 formed with the protective layer 3 is transferred, first a heat release tape is attached to the protective layer 3, and then the transfer head is moved until the transfer head and the soft template 2 are bonded and fixed by the heat release tape, next the transfer head is moved, and the transfer head drives the soft template 2 fixedly connected thereto to move to the stitching area of the base substrate 1, finally since the heat release tape is evaporated and released when heated, the heat release tape is heated and released by heating the heat release tape, thereby the soft template 2 is separated from the transfer head, and the soft template 2 can be moved relatively easily and conveniently by the above process, and the moving process is easy to realize without causing damage to the soft template 2. In order to realize the convenience and less damage of the transfer of the soft template 2, it is not limited to the above-mentioned method of the heat release tape, and may be other moving structures and methods that can meet the requirements.

In some embodiments, the step S104 of fixing at least one soft template 2 on the base substrate 1 specifically includes: heating the base substrate 1 until the soft template 2 is fixed on the base substrate 1.

In the above manufacturing method of the nano-imprint template, in order to fix the soft templates 2 on the base substrate 1, the method of heat treatment may be used to increase the adhesion between the soft templates 2 and the base substrate 1 by heating the base substrate 1 to fix the soft templates 2 on the base substrate 1. The above-described method of heating and fixing is relatively simple and easy to implement, and in order to meet the fixing requirements of the base substrate 1 and the soft templates 2, other ways can be used.

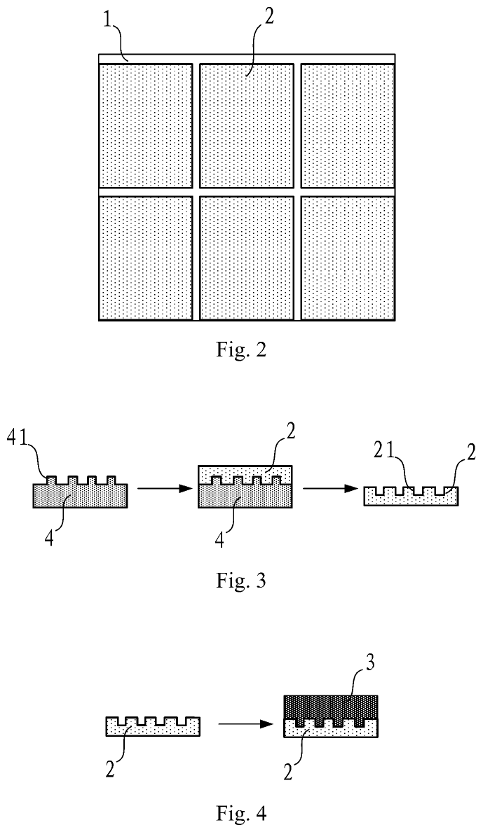

Based on the same inventive concept, as shown in the figure, an embodiment of the present disclosure further provides a nano-imprint template manufactured by using the manufacturing method of any one of the above technical solutions. As shown in FIG. 2, the nano-imprint template includes: a base substrate 1; a plurality of soft templates 2 fixed on the base substrate 1, and the side of at least one of the soft templates 2 away from the base substrate 1 is provided with a groove 21.

In the above nano-imprint template, the groove 21 of each soft template 2 corresponds to partial graphic information of the nano-imprint template, and the graphic information of the manufactured nano-imprint template is stitched, and the overall thickness of the nano-imprinting template, including the soft templates 2, prepared by the manufacturing method of the nano-imprinting template is the same, and there is no height difference at the stitching seam, which solves the problem of imprinting loss caused by the height difference of the nano-imprint template at the stitching seam and the problem of larger stitching seam, thereby the imprinting quality at the stitching seam is good, and the product yield of the large-sized nano-imprint template is improved.

In some embodiments, the soft templates 2 can be prepared by using a silica gel material or a resin material, and can also be prepared by using other materials that meet the requirements.

In some embodiments, the soft templates 2 can be heated and cured on the base substrate 1, and other fixing means that meet the requirements can also be used.

In some embodiments, the height difference of any two adjacent soft templates is about 0.

In the manufacturing method of the nano-imprint template provided by the embodiments of the present disclosure, first the soft template is formed by a master, and the groove on each soft template corresponds to the preset pattern on the corresponding master, that is, each of the soft templates has partial graphic information of the nano-imprint template. Then, the protective layer is formed on the side of the soft template provided with the groove, to protect the groove of the soft template from damage during subsequent movement and process, afterwards, the soft templates are moved one by one into the stitching areas of the base substrate and each of the soft templates is fixed on the base substrate. Finally, the protective layer on each soft template is removed, and in this way, a plurality of soft templates are fixed on the base substrate, the grooves of the plurality of soft templates correspond to the graphic information of the nano-imprint template, thereby the stitching manufacturing of the nano-imprint template is completed. Compared with the stitching process in the related art, since the stepwise dispensing of the glue is not involved in the stitching process, the same method is used to prepare a plurality of soft templates and the soft templates are fixed on the substrate, so that the overall thickness of the nano-imprint template is uniform, and there is no height difference at the stitching seam. The problem of imprinting loss caused by the height difference of the nano-imprint template at stitching seam and the problem of the larger stitching seam are solved, so that the imprinting quality at the stitching seam is good, and the product yield of the large-sized nano-imprint templates has been improved.

It is apparent that those skilled in the art can make various modifications and variations to the disclosure without departing from the spirit and scope of the disclosure. Thus, if these modifications and variations of the present disclosure fall within the scope of the claims and the equivalents thereof, it is intended that the present disclosure covers the modifications and modifications.

1. A manufacturing method of a nano-imprint template, comprising:
forming a soft template on a side of at least one master provided with a preset pattern, wherein the soft template is provided with a groove corresponding to the preset pattern;
forming a protective layer on a side of the soft template provided with the groove;
moving at least one soft template formed with the protective layer into a stitching area of a base substrate;
fixing the at least one soft template on the base substrate, wherein a side of the soft template away from the protective layer contacts with the base substrate; and
removing the protective layer.

2. The manufacturing method according to claim 1, wherein forming the soft template on the side of the at least one master provided with the preset pattern comprises:
coating a silica gel material or a resin material on the side of the at least one master provided with the preset pattern; and
curing the silica gel material or the resin material to form the soft template.

3. The manufacturing method according to claim 1, wherein forming the protective layer on the side of the soft template provided with the groove comprises: coating a soluble resin material on the side of the soft template provided with the groove.

4. The manufacturing method according to claim 3, wherein removing the protective layer comprises: dissolving the soluble resin material.

5. The manufacturing method according to claim 3, wherein the soluble resin material is Polyvinyl Alcohol.

6. The manufacturing method according to claim 1, wherein moving at least one soft template formed with the protective layer into the stitching area of a base substrate comprises:
bonding the protective layer and a transfer head by a heat release tape to fix the soft template formed with the protective layer to the transfer head;
moving the transfer head into the stitching area of the base substrate; and
heating the heat release tape until the soft template is detached from the transfer head.

7. The manufacturing method according to claim 1, wherein fixing the at least one soft template on the base substrate comprises: heating the base substrate until the soft template is fixed on the base substrate.

8. A nano-imprint template, comprising:
a base substrate; and
a plurality of soft templates fixed on the base substrate, wherein a side of at least one of the soft templates away from the base substrate is provided with a groove.

9. The nano-imprint template according to claim 8, wherein the soft templates are prepared by using a silica gel material or a resin material.

10. The nano-imprint template according to claim 9, wherein a height difference of any two adjacent ones of the soft templates is about 0.
